(19) United States
(12) Patent Application Publication
(10) Pub. No.: US 2008/0124833 A1
(43) Pub. Date: May 29, 2008

(54) METHOD FOR FILLING HOLES WITH METAL CHALCOGENIDE MATERIAL

(75) Inventors: Ricardo Ruiz, San Jose, CA (US); Delia J. Milliron, Menlo Park, CA (US); Simone Raoux, Santa Clara, CA (US); David B. Mitzi, Mahopac, NY (US); Alejandro G. Schrott, New York, NY (US)

Correspondence Address: CONNOLLY BOVE LODGE & HUTZ LLP;(FOR IBM YORKTOWN), P.O. BOX 2207, WILMINGTON, DE, 19899-2207, US

(73) Assignee: International Business Machines Corporation, Armonk, NY (US)

(21) Appl. No.: 11/556,385

(22) Filed: Nov. 3, 2006

(51) Int. Cl. H01L 45/00; G03F 7/00

(52) U.S. Cl. 438/102; 430/296; 430/311; 257/E45.002

(57) ABSTRACT

A metal chalcogenide material is deposited into holes within a substrate surface. The method comprises obtaining a hydrophilic substrate surface; obtaining a solution of a hydrazine-based precursor of a metal chalcogenide; applying the solution onto the substrate to fill the holes with said precursor; and thereafter annealing the precursor to convert said precursor to said metal chalcogenide thereby producing holes in the substrate surface filled with a metal chalcogenide material.

### TECHNICAL FIELD

The present disclosure relates to a method for filling holes with metal chalcogenide material. The present disclosure is especially advantageous for filling nano and micro scale holes or vias in a surface of a substrate.

### BACKGROUND

Interest in using phase change materials (PCM) for microelectronic non-volatile memory devices has existed for several decades. The reason for this interest is based on the properties of these materials (generally metal chalcogenide alloys), which exhibit a ratio of resistivities in the amorphous over the crystalline phase of several orders of magnitude. More recently, progress in lithographic and deposition techniques have provided new momentum towards the realization of practical Phase Change Memory devices.

However, challenges regarding the power budget remain, and a practical cell requires decreasing the size of the switching volume. The challenge thus is to provide a design that reduces the physical volume of that part of the memory cell that contains the active switching, while maintaining the desired properties of the material and contacts. It is also desired that this design be easily and inexpensively integrated into an existing CMOS Logic manufacturing flow.

Many of these cell designs call for filling a feature such as a via hole with the PCM in order to form the memory element. This step is usually done by a sputter deposition technique that requires a high degree of collimation. Sputtering requires expensive tools and targets and does not provide flexibility for material optimization.

More recently, processes whereby thin films of metal chalcogenides can be deposited using precursor solutions prepared by dissolving a metal chalcogenide or mixture of metal chalcogenides in a hydrazine (or hydrazine-like) solvent with, optionally, extra chalcogen added to improve solubility and film formation have been disclosed. See U.S. Pat. Nos. 6,875,661 and 7,094,651; and U.S. patent application Ser. No. 11/0,955,976 disclosures of which are incorporated herein by reference. Alternatively, the precursor solution may be prepared (see U.S. patent application Ser. No. 11/432,484, disclosure of which is incorporated herein by reference) by dissolving an elemental metal or mixtures of metals in a hydrazine (or hydrazine-like) solvent, with at least enough chalcogen added to enable the formation of the stoichiometric metal chalcogenide in solution.

The hydrazine-precursor technique has the advantage of being a high-throughput process, which does not require high temperatures or high vacuum conditions for the film deposition. The hydrazine precursor process thereby has the potential for being low-cost and suitable for deposition on a wide range of substrates, including those that are flexible. As metal chalcogenides can exhibit a wide range of electronic character, it may be used to prepare high-quality semiconducting, insulating or metallic films. The process has been used to deposit, for example, both n- and p-type semiconducting films for use as channel layers in thin-film transistors (TFTs), exhibiting field-effect mobilities >10 cm²/V-s—approximately an order of magnitude better than previous results for spin-coatable semiconductors [see “High Mobility Ultrathin Semiconducting Films Prepared by Spin Coating, Nature, vol. 428, 299 (2004)].

Besides TFTs, other electronic devices that rely on metal chalcogenide films can also be prepared using the described techniques. Solar cells, for example, may contain thin n-type chalcogenide semiconductor layers (˜0.25 μm) deposited on a p-type substrate, with electrical contacts attached to each layer to collect the photocurrent. Light-emitting diodes (LEDs) are typically comprised of a p-n bilayer, which under proper forward bias conditions emits light.

Rewriteable phase-change memory devices generally employ a film of a chalcogenide-based phase-change material, which must be switchable between two physical states (e.g., amorphous-crystalline, crystalline phase 1-crystalline phase II). The state of the phase change material must also be detectable using some physical measurement (e.g., optical absorption, optical reflectivity, electrical resistivity, index of refraction).

As an example, commercially-available rewritable optical memory devices generally rely on a film of a metal chalcogenide material such as Ge₂Sb₂Te₅ or KSb₅S₈ [see “KSb₅S₈: A Wide Bandgap Phase-Change Material for Ultra High Density Rewritable Information Storage,” Adv. Mater., vol. 15, 1428, 2003]. Initially the film is amorphous, but may be converted to a crystalline form using a laser beam of sufficient intensity to heat the material above the crystallization temperature. Subsequent exposure to a more intense and short laser pulse melts the crystallized chalcogenide phase-change material, resulting in a conversion to an amorphous state upon quenching. A recorded bit is an amorphized mark on a crystalline background. The reversibility of the crystallization-amorphization process allows for the fabrication of rewritable memory [see A. V. Kolobov, “Understanding the phase change mechanism of rewritable optical media, Nature Mater., vol. 3, 703, 2004]. Generally the chalcogenide materials in the above-described applications are deposited using vacuum-based techniques such as sputtering or thermal evaporation.

However, such processes could stand improvement, for instance, from the viewpoint of reduced complexity, reduced cost and improved throughput.

### SUMMARY OF DISCLOSURE

The problem addressed in this disclosure is filling pre-formed small (nano to micro) scale holes in an otherwise flat substrate surface with a high quality chalcogenide material for a variety of electronic applications involving nano to micro scale features (e.g. phase change memory, nanocomposite solar cells, transistors).

This disclosure involves filling preformed holes, such as micro to nanoscale holes, in a substrate with a chalcogenide material by depositing a precursor to the metal chalcogenide into those holes from solution and then thermally converting that precursor to the metal chalcogenide. The thermal conversion can be carried out at relatively low temperatures. The method of this disclosure employs previously developed methods for solution casting metal chalcogenide thin films in order to fill holes which are difficult to fill by other means, such as sputter deposition. The surface chemistry of the substrate, particularly in the holes, is controlled to encourage wetting inside the hole during the solution deposition process so that the drying process leaves the solid metal chalcogenide precursor behind in the holes.

Because these precursors can be decomposed at low temperature to yield high quality materials, the final product can be obtained under mild conditions which will not damage the fine pattern that forms the holes, even when the pattern is formed in a polymer layer. The solution-based process employed according to this disclosure makes possible reduced complexity of the process (reducing cost and improving throughput) and the ability to deposit on a wider range of substrate types (including those that have very large area or are flexible) and surface morphologies.

One advantage of the above-described hydrazine-precursor process is that, since it relies on deposition from a solution that can flow across a surface and therefore fill surface features on a substrate, it should provide a means of covering a wider range of surface morphology than enabled by more traditional techniques based, for example, on thermal evaporation or sputtering (which rely on line-of-sight deposition).

Accordingly, the current disclosure describes a method of employing the hydrazine-based deposition technique for filling vias, channels and holes with chalcogenide-based materials. These filled substrate features are useful for a number of device applications, especially for use within phase change memories.

In particular, the present disclosure relates to method of depositing a metal chalcogenide material into holes within a substrate surface which comprises obtaining a hydrophilic substrate surface; obtaining a solution of a hydrazine-based precursor of a metal chalcogenide; applying the solution onto the substrate to fill the holes with the precursor; and thereafter annealing the precursor to convert the precursor to the metal chalcogenide thereby producing holes in the substrate surface filled with a metal chalcogenide material.

Still other objects and advantages of the present disclosure will become readily apparent by those skilled in the art from the following detailed description, wherein it is shown and described only in the preferred embodiments, simply by way of illustration of the best mode. As will be realized, the disclosure is capable of other and different embodiments, and its several details are capable of modifications in various obvious respects, without departing from the spirit of the disclosure. Accordingly, the description is to be regarded as illustrative in nature and not as restricted.

### SUMMARY OF DRAWINGS

FIG. 1 is a schematic view of holes 10 in substrate 20.

FIGS. 2A and 2B are Cross-sectional SEM images of an indium-telluride-coated substrate (substrate type A), with conformal filling of holes. A single coating of indium telluride was used.

FIG. 3 is a Cross-sectional SEM image of an indium-telluride-coated substrate (substrate type A), with conformal filling of holes. Three iterations of indium were used.

FIGS. 4A and 4B are Cross-sectional SEM images of an indium-telluride-coated substrate (substrate type B), with conformal filling of holes and channels. Four iterations of the indium telluride coating process were employed.

FIG. 5 is a Cross-sectional SEM image of a layered indium telluride/KSb₅S₈ coated substrate (substrate type A), with conformal filling of holes and appearance of two distinct layers. The darker bottom layer is the indium telluride, while the lighter material on top is the KSb₅S₈. Two iterations of the indium telluride coating process and two iterations of the KSb₅S₈ process were employed.

FIGS. 6A-6I are SEM images that show the chalcogenide material CuInSe(2-x)S(x) filling holes.

FIGS. 7A and 7B are SEM images that show vias filled with Sb(1-x)Se(x).

FIG. 8 is an SEM image showing vias completely filled with Ge doped Sb(1-x)Se(x).

### BEST AND VARIOUS MODES FOR CARRYING OUT DISCLOSURE

As discussed above, the present disclosure relates to method of depositing a metal chalcogenide material into holes within a substrate surface which comprises obtaining a hydrophilic substrate surface; obtaining a solution of a hydrazine-based precursor of a metal chalcogenide; applying the solution onto the substrate to fill the holes with the precursor; and thereafter annealing the precursor to convert the precursor to the metal chalcogenide thereby producing holes in the substrate surface filled with a metal chalcogenide material.

A solution of the metal chalcogenide material can be prepared using one of the techniques disclosed in U.S. Pat. Nos. 6,875,661 and 7,094,651; and U.S. patent application Ser. No. 11/0,955,976 and Ser. No. 11/432,484, US Patent Publication 2005-0009225 and US Patent Application Publication 2005-0158909. Generally, the process involves dissolving a metal chalcogenide in hydrazine (or a hydrazine-like solvent) at near ambient temperatures, with optionally extra chalcogen added to improve solubility. Typical hydrazine compounds are represented by the formula:

R¹R²N—NR³R⁴

Wherein each of R¹, R², R³ and R⁴ is independently hydrogen, aryl such as phenyl, a linear or branched alkyl having 1-6 carbon atoms such as methyl, ethyl or a cyclic alkyl of 3-6 carbon atoms. The most typical solvent is hydrazine. The present disclosure is not limited to the use of hydrazine, but it can also be used with hydrazine-like solvents, as disclosed above, such as 1,1-dimethylhydrazine and methylhydrazine or mixtures of hydrazine-like solvents with other solvents including, but not limited to, water, methanol, ethanol, acetonitrile and N,N-dimethylformamide. However, with certain highly-reactive metals, e.g. K and other alkali metals, it is preferred that the solvent be anhydrous.

The solution may also be prepared by directly dissolving the corresponding metal of the metal chalcogenide in hydrazine, with at least enough chalcogen added to affect the formation and dissolution of the metal chalcogenide in solution (U.S. patent application Ser. No. 11/432,484). Alternatively, the solution may be formed by dissolving a preformed hydrazinium-based precursor in a non-hydrazine-based solvent, such as a mixture of ethanolamine and DMSO, as described in U.S. Pat. No. 7,094,651.

In another method for preparing the solution, a chalcogenide and an amine are first contacted to produce an ammonium-based precursor of the metal chalcogenide, which is then contacted with a hydrazine compound and optionally, an elemental chalcogen. This method includes the steps of:

contacting at least one metal chalcogenide and a salt of an amine compound with H₂S, H₂Se or H₂Te, wherein the amine compound is represented by the formula:

NR⁵R⁶R⁷

wherein each of R⁵, R⁶, and R⁷ is independently hydrogen, aryl such as phenyl, a linear or branched alkyl having 1-6 carbon atoms such as methyl, ethyl or a cyclic alkyl of 3-6 carbon atoms, to produce an ammonium-based precursor of the metal chalcogenide;

contacting the ammonium-based precursor of the metal chalcogenide, a hydrazine compound represented by the formula:

R¹R²N—NR³R⁴

wherein each of R¹, R², R³ and R⁴ is independently hydrogen, aryl such as phenyl, a linear or branched alkyl having 1-6 carbon atoms such as methyl, ethyl or a cyclic alkyl of 3-6 carbon atoms, and optionally, an elemental chalcogen, such as S, Se, Te or a combination thereof, to produce a solution of a hydrazinium-based precursor of the transition metal chalcogenide in the hydrazine compound.

Typically, the amine compound is NH₃, CH₃NH₂, CH₃CH₂NH₂, CH₃CH₂CH₂NH₂, (CH₃)₂CHNH₂, CH₃CH₂CH₂CH₂NH₂, phenethylamine, 2-fluorophenethylamine, 2-chlorophenethylamine, 2-bromophenethylamine, 3-fluorophenethylamine, 3-chlorophenethylamine, 3-bromophenethylamine, 4-bromophenethylamine, 2,3,4,5,6-pentafluorophenethylamine or a combination thereof.

Examples of suitable metals for the metal chalcogenide are both the transition and non-transition metals and include tin, germanium, lead, indium, antimony, mercury, gallium, thallium, potassium, copper, iron, cobalt, nickel, manganese, tungsten, molybdenum, zirconium, hafnium, titanium, and niobium or a combination thereof. The chalcogen is typically S, Se, Te or a combination thereof.

The concentration of the metal chalcogenide precursor in the hydrazine compound is typically no more than about 10 molar and more typically about 0.01 molar to about 10 molar, even more typically about 0.05 to about 5 molar, or about 0.05 to about 1 molar.

In one embodiment, the metal chalcogenide can be represented by the formula MX or MX₂ wherein M is a main group or non-transition metal such as potassium, germanium, tin, lead, antimony, bismuth, gallium, indium and tellurium or a transition metal such as copper, iron, cobalt, nickel, manganese, tungsten, molybdenum, zirconium, hafnium, titanium, and niobium or a combination thereof and wherein X is a chalcogen, such as, S, Se, Te or a combination thereof.

In another embodiment, the metal chalcogenide can be represented by the formula M₂X₃ wherein M is a metal, such as lanthanum, yttrium, gadolinium and neodymium or a combination thereof and wherein X is a chalcogen, such as, S, Se Te or a combination thereof.

In yet another embodiment, the metal chalcogenide can be represented by the formula M₂X wherein M is Cu or K and wherein X is a chalcogen, such, as S, Se, Te or a combination thereof.

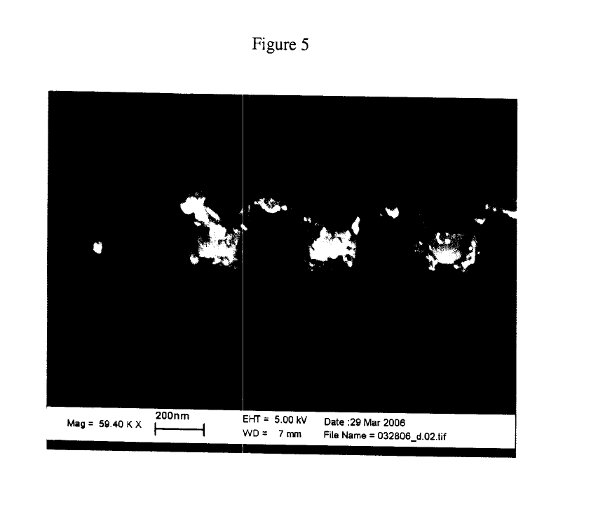

The metal chalcogenide precursor films are deposited using the solutions prepared as disclosed above on a substrate (containing holes, vias or channels) using standard solution-based techniques such as spin-coating, stamping, printing, doctor blading, or dipping. The substrate, which contains the holes, vias and/or channels to be filled, desirably is typically free of contaminants, and may be prepared for solution deposition by cleaning and/or surface pretreatment. In addition, the surface is hydrophilic whereby the contact angle of the solution on to the surface is less than 90 degrees and more typically less than 50 degrees. Cleaning can be accomplished by sonication in a variety of solvents, such as ethanol, methanol or acetone and/or by heating in various cleaning solutions, such as sulfuric acid/hydrogen peroxide (Piranha) or ammonium hydroxide solutions. The cleaning can also be carried out using UV-ozone or oxygen plasma. Surface pretreatment may include depositing a molecular monolayer to modify substrate wetting and/or film adhesion characteristics for depositing a film of an inorganic (e.g., oxide-, chalcogenide- or halide-based) material on the surface to improve film formation. This surface film could in also, in principle, be deposited from solution. A wetting enhancement layer of a material that lines the holes conformally can be employed, including depositing this layer from solution. For instance, see FIG. 5, wherein In2Te3 is deposited first as a wetting enhancement layer for the KSb5S8. During the deposition process, the solution containing the precursor flows into the holes, vias and channels and therefore, upon drying, leaves a deposit of the metal chalcogenide precursor.

A low-temperature thermal treatment is used to decompose the resulting metal chalcogenide precursor film on the substrate, resulting in the formation of a metal chalcogenide film that conformally fills the surface features on the substrate. The thermal treatment is typically about 50° C. to about 500° C., and more typically about 100° C. to about 350° C. The amount of time of the thermal treatment is typically just sufficient to decompose the precursor, which is usually about 5 seconds to about 1 hour. More typically, the thermal treatment is about 10 minutes to about 30 minutes. The thermal treatment may be applied using a hot plate, oven (tube- or box-type), laser-based rapid annealing rapid thermal processing or microwave-based heating.

Optionally, the process may be iterated more than one time to put down multiple layers of the same material (to create a thicker layer in the via, hole or channel) or using multiple compounds (to create stacks of different materials in the via, hole or channel).

The present disclosure may be used in the preparation and integration of electrical devices, including phase-change memory devices (e.g., optical rewritable memory or PRAM), transistors, solar cells or LEDs.

The materials which can be prepared by these methods include both n- and p-type semiconductors of interest for TFTs, as well as phase change materials such as Sb(1-x)Se(x), and optical glass forming materials such as Ge(1-x)Se(x). This broad range of materials can all be used especially to fill micro- and nanoscale holes using the methods of the current disclosure.

The holes can be formed from inorganic materials such as Si, SiO₂ or SiN or TiN, or from organic materials such as polymers including resists and block-copolymers. For example, the holes might be vias created by photo- or e-beam lithography in SiO₂, or patterns created lithographically in a resist film, or nanoscale holes created by selective displacement or removal of one block from a block copolymer film. The substrate with holes is first prepared to facilitate the solution filling the holes in order to make the area inside the holes wettable by the solvent used. The exact procedure used depends on the nature of the substrate and on the material being deposited in the holes.

The holes can have similar lateral dimensions in the plane of the substrate and those dimensions are typically about 20 to about 1000 nm. In one embodiment the holes have one lateral dimension of about 20 to about 1000 nm and the other lateral dimension which exceeds the first by greater than about 2 times. In another embodiment, the holes have similar lateral dimensions in the plane of the substrate and those dimensions are in the range of less than about 20 nm. Likewise, the substrate can include trenches having similar dimensions as the holes.

If desired, smaller size range holes may be ordered, at high pitch, using patterns formed by block copolymers. For example, patterns can formed by diblock copolymer thin-films as a liftoff mask or as a lithography mask to pattern chalcogenide thin-films. In one embodiment, periodic patterns can be formed on chalcogenide thin films, by applying a layer of a block copolymer that comprises two or more different polymeric block components that are immiscible with one another and that form a periodic pattern defined by repeating structural units where one of the two blocks can be then removed. The block copolymer layer is applied over a substrate that may or may not comprise a substrate surface topography. The repeating structural units may or may not be aligned in a predetermined direction. A layer of chalcogenide material to fill in the structure formed by the block copolymer film is then applied.

A typical chalcogenide structure comprises a periodic array of circular structures (discs or dots) comprising a chalcogenide material. The circular structures are arranged in an hexagonal distribution with the circle diameter equal to or less than 50 nm and more typically with diameters ranging from 10-30 nm. The center to center distance being equal to or less than 100 nm and more typically from 20-60 nm.

Another structure comprises a periodic array of striped structures comprising a chalcogenide material. The width of the striped structures being equal or less than 50 nm and more typically 10-30 nm and a center-to-center distance equal to or less than 100 nm and more typically 20-60 nm. The striped pattern may or may not be aligned to a particular direction.

Also, lithographically templated structures that include regions of chalcogenide materials embedded within a lithographically patterned inorganic matrix can be provided. More particularly, such a method employs electron beam or photolithography to pattern holes (or vias) into an inorganic substrate such as silica, silicon, or silicon nitride and uses these holes to pattern embedded regions of chalcogenide materials.

The technique comprises creating an arbitrary pattern of holes and/or trenches in a substrate using electron beam or photolithography. The holes and/or trenches may have an aspect ratio exceed 1, meaning they are deeper than at least one and possible both of their lateral dimensions. A layer of chalcogenide material to fill in the structure formed by lithography is then applied. Also, periodic patterns on chalcogenide thin films can be formed.

The following non-limiting examples are presented to further illustrate the present disclosure.

### EXAMPLE 1

### In₂Te₃

The solution used for spin-coating is prepared by stirring at room temperature (in an inert atmosphere) 0.5 mmol of elemental indium (57.4 mg) and 0.75 mmol of tellurium (95.7 mg) in 3 mL of distilled hydrazine. After stirring for approximately 1 week, only a small amount of the indium remains undissolved and an orange-yellow solution is formed. The solution is filtered to remove the remaining metal and is then ready for spin coating.

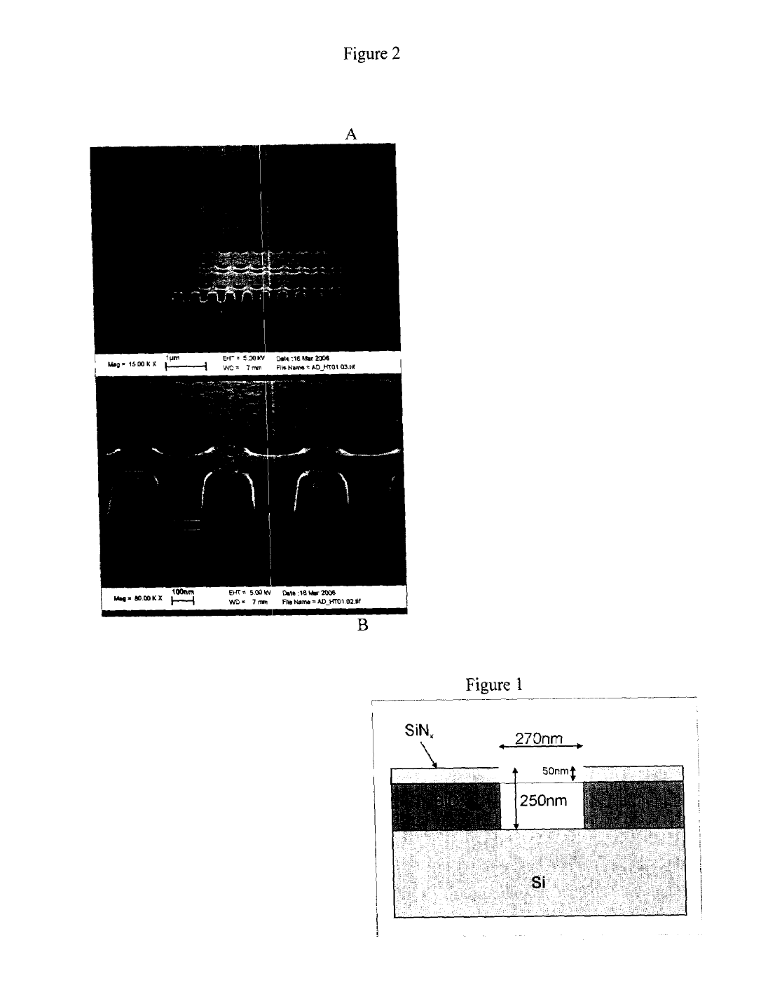

Two types of substrates are employed to test surface feature filling. In substrate A, the surface of the substrate is covered with holes that have an approximately 1:1 aspect ratio as shown in FIG. 1. In substrate B, the surface is covered with similar holes and channels, but rather provides a more abrupt aspect ratio of approximately 3.5:1. In each case, the substrates are cleaned by sonicating alternately in ethanol, dichloromethane and ethanol and are finally subjected to a 15 minute dip in a solution consisting of approximately a 1:3 ratio (by volume) of ammonium hydroxide and water. This latter step provides a suitable hydrophilic surface on the substrate for spin coating. The substrates are then dried using compressed air and transferred into a nitrogen-filled drybox for the spin coating process.

The spin-coating process involves depositing several drops of the precursor solution on the substrate and initiating the spinning cycle (after making sure the drops have spread to cover approximately the entire substrate). The spin cycle consists of ramping to 150 rpm for 2 seconds and then ramping in 2 seconds to between 2500 and 3000 rpm and maintaining this rotation for 60 seconds. Note that this solution-coating process is representative and could alternatively be achieved using other solution-based processing procedures, such as dipping, stamping or printing.

After depositing the precursor film, the coated substrates are placed on a hot plate at 125° C. for 5 minutes and then gradually heated to 155° C. over a period of 60 minutes. Finally, the temperature is gradually raised to 250° C. over a period of 10 minutes and maintained at this temperature for an additional 10 minutes.

The substrate, which now has an indium telluride coating on it, is cooled and is ready for evaluation. RBS (Rutherford Back Scattering) analysis of an analogous film prepared on a silicon substrate (with thermal oxide coating and no holes, vias or channels) yielded 42(1) % indium and 57(1) % tellurium, which is consistent with the expected 2:3 In:Te stoichiometry. An X-ray diffraction pattern of an analogously prepared drop cast film on a quartz substrate was consistent with that for In₂Te₃ [PDF card 33-1488]. FIGS. 2a and 2b show two cross-sectional SEM images of coated substrates (substrate type A with 1:1 aspect ratio holes) showing good coverage across the wafer and into the holes.

### EXAMPLE 2

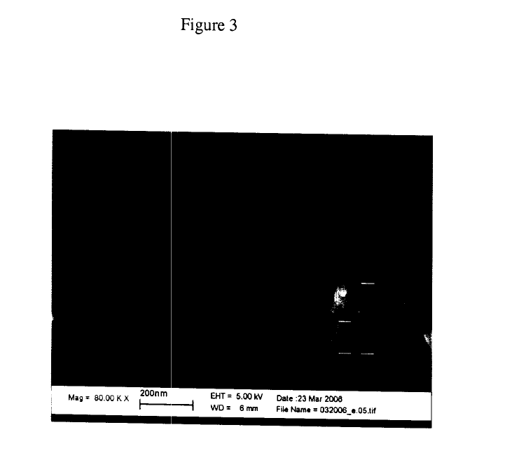

To demonstrate thicker coatings, it was necessary to apply several coatings of the indium telluride film. In FIG. 3, a substrate with three iterations of the film coating process described above is shown. Note the more complete hole filling by the indium telluride material. Attempts to produce thick films by using a much more concentrated solution or by using a slower spin speed (or by drop casting instead of spin coating) generally yielded films that exhibited a substantial amount of porosity, as a result of the need to remove gaseous products during the decomposition process. Therefore, the multiple deposition process is preferable for achieving a thick coating.

### EXAMPLE 3

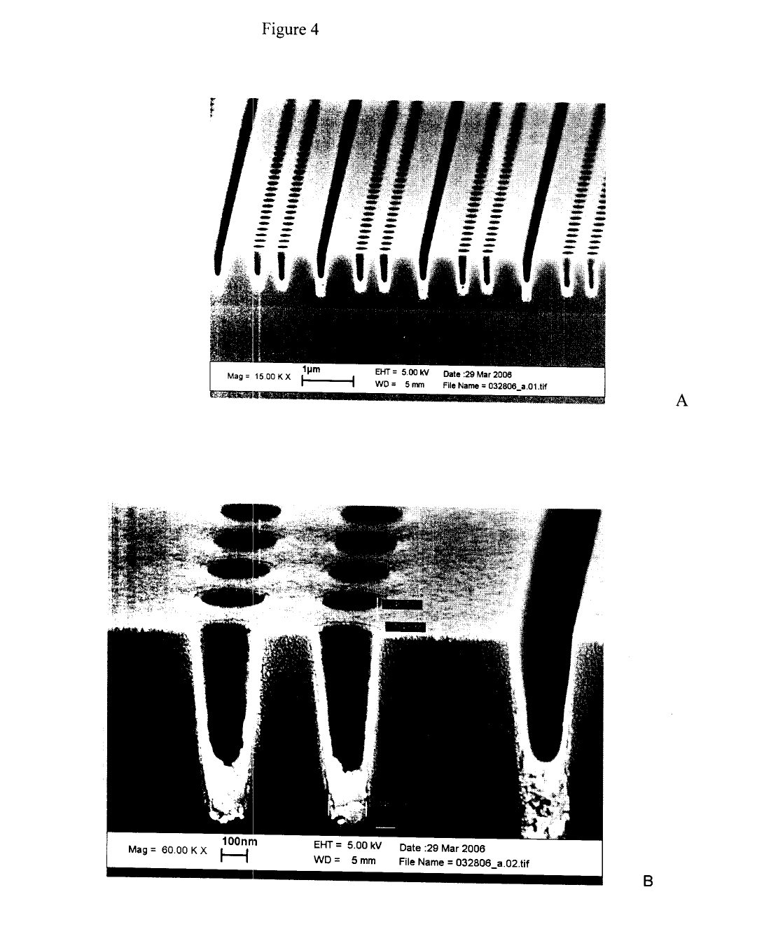

To illustrate the filling of larger aspect ratio features using the hydrazine-based solution approach, type B substrates (with approximately 3.5:1 aspect ratio features) were similarly processed and yielded the results shown in FIG. 4. Note that the holes and channels are adequately filled by the spin-coating process.

### EXAMPLE 4

### KSb₅S₈

The KSb₅S₈ solution can be prepared as described in U.S. Ser. No. 11/432,848. Under rigorously inert atmosphere conditions, 0.5 mmol of elemental K (19.6 mg; Alfa Aesar, 99.95%, ampouled under Ar) are combined with 2.5 mmol Sb (304.4 mg; Alfa Aesar; 99.999%, −200 mesh), 8.0 mmol S (256.5 mg; Aldrich, 99.998%) and 5.0 mL anhydrous distilled hydrazine. The hydrazine is added very carefully (drop-by-drop and very slowly) to accommodate the highly exothermic reaction. The mixture is stirred for 5 days at room temperature in a nitrogen-filled drybox, forming an essentially clear relatively viscous yellow solution (tiny amount of black precipitate or undissolved material is still present but can be easily removed using a filter).

One method to overcome the highly exothermic nature of the reaction between potassium and hydrazine is to have the potassium physically removed from the bottom of the reaction vessel (e.g., K is “sticky” at room temperature and will effectively stick to the side of the glass walls of the reaction flask). Then, when the hydrazine drops are placed on the bottom of the reaction flask, the vapors can first be allowed to react, followed by gentle agitation of the vessel, allowing some of the drop to gradually come into contact with the remaining potassium. Further techniques to accommodate the highly exothermic nature of the reaction are to dilute the hydrazine with an appropriate co-solvent and/or to cool the reaction flask.

For thin-film deposition, the above-described solution was further diluted by mixing 1 mL of the above described precursor solution with 2 mL of anhydrous hydrazine. Films could then be spin coated from this diluted hydrazine-based precursor solution onto A-type substrates (described above for the In₂Te₃ example) using the same spin-coating process to that described above for In₂Te₃. In contrast to the In₂Te₃ example; however, the KSb₅S₈ films did not adequately wet the substrate surface during film formation, thereby resulting in film discontinuity across the surface (although material did deposit in the holes). To improve surface wetting and adhesion, an In₂Te₃ layer was first deposited on the substrate and then the KSb₅S₈ layer was placed on top. As seen in FIG. 5, the KSb₅S₈ deposits effectively in the holes. The darker bottom layer is the indium telluride, while the lighter material on top is the KSb₅S₈. Two iterations of the indium telluride coating process and two iterations of the KSb₅S₈ process were employed. There is still some roughness to the film outside the holes, which may be attributed to partial dissolution of the film during the various iterations of film deposition (2 depositions of In₂Te₃ and 2 interations of KSb₅S₈). Improved surface treatments (adhesion layers and/or processes to affect the wetting of the precursor solution) or use of a different solvent during spin coating should help to reduce this effect and improve the resulting film morphology.

As described in U.S. Ser. No. 11/432,848, KSb₅S₈ films, deposited analogously to that described above, exhibit the expected phase-change properties as a function of temperature and are therefore interesting for potential use in a variety of memory-type applications.

### EXAMPLE 5

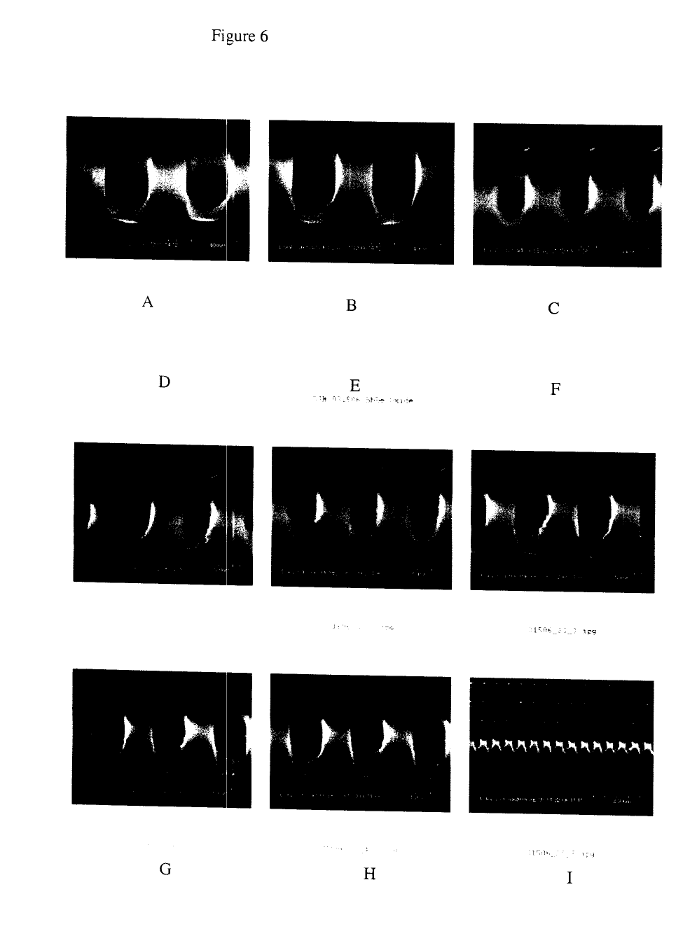

FIGS. 6A-6B are SEM images that show the chalcogenide material CuInSe(2-x)S(x) (bright contrast) filling a pattern of ca. 20 nm holes formed using the self-assembled pattern of a thin-film of Poly(styrene-b-methylmethacrylate) (PS-PMMA) diblock copolymer. In this case, the holes are formed by selective displacement of the PMMA block using glacial acetic acid and the substrate is prepared for spin casting with a brief (few seconds) UV-ozone treatment. This serves the dual purpose of cleaning remaining PMMA material from the nanoscale holes and also providing a suitably hydrophilic substrate for spin casting. The CuInSe(2-x)S(x) is deposited from solution using the methods described in YOR920050040US1.

### EXAMPLE 6

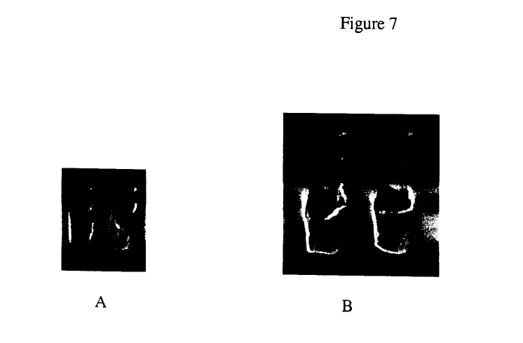

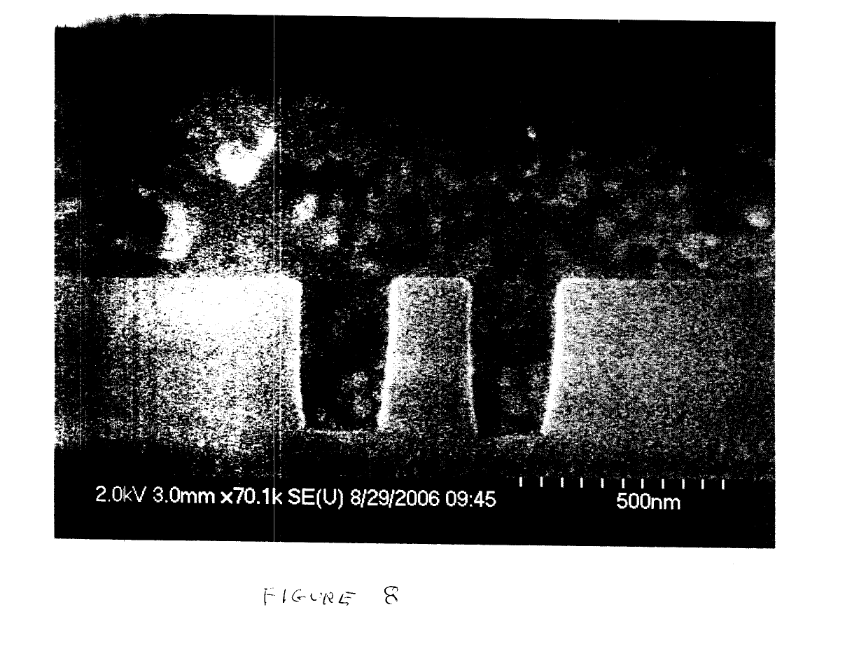

Vias with aspect ratio approx 2:1 are filled with Sb(1-x)Se(x). For this material, selective deposition into the vias is achieved using a 30 min and 130 C soak in piranha solution (approx 4:1 sulfuric acid to hydrogen peroxide) as the final surface preparation step. Solvents including dimethylsulfoxide (DMSO), N-methylformamide (NMF), hydrazine, and mixtures of these were all observed to result in selective filling of vias. The results are illustrated in FIGS. 7A and 7B. More complete filling of similar vias by Sb(1-x)Se(x) and Ge-doped Sb(1-x)Se(x) could be achieved through spin coating from a more concentrated solution or by dip coating. Complete filling of vias is possible by drop casting, with result as illustrated in FIG. 8.

The term “comprising” (and its grammatical variations) as used herein is used in the inclusive sense of “having” or “including” and not in the exclusive sense of “consisting only of.” The terms “a” and “the” as used herein are understood to encompass the plural as well as the singular.

The foregoing description illustrates and describes the present disclosure. Additionally, the disclosure shows and describes only the preferred embodiments of the disclosure, but, as mentioned above, it is to be understood that it is capable of changes or modifications within the scope of the concept as expressed herein, commensurate with the above teachings and/or skill or knowledge of the relevant art. The described hereinabove are further intended to explain best modes known of practicing the invention and to enable others skilled in the art to utilize the disclosure in such, or other embodiments and with the various modifications required by the particular applications or uses disclosed herein. Accordingly, the description is not intended to limit the invention to the form disclosed herein. Also it is intended that the appended claims be construed to include alternative embodiments.

All publications, patents and patent applications cited in this specification are herein incorporated by reference, and for any and all purposes, as if each individual publication, patent or patent application were specifically and individually indicates to be incorporated by reference. In this case of inconsistencies, the present disclosure will prevail.

What is claimed is:

1. A method of depositing a metal chalcogenide material into holes within a substrate surface which comprises:
obtaining a hydrophilic substrate surface;
obtaining a solution of a hydrazine-based precursor to a metal chalcogenide;
applying the solution onto the substrate to fill the holes with said precursor;
and thereafter annealing the precursor to convert said precursor to said metal chalcogenide thereby producing holes in the substrate surface filled with a metal chalcogenide material.

2. The method of claim 1 wherein said solution is prepared by directly dissolving a metal chalcogenide in a hydrazine compound and optionally an excess of chalcogen.

3. The method of claim 1 wherein said solution is prepared by contacting an isolated hydrazine-based precursor of a metal chalcogenide and a solvent to form a solution thereof.

4. The method of claim 1 wherein said solution is prepared by directly dissolving the corresponding metal of the metal chalcogenide in a hydrazine compound, with at least enough chalcogen added to affect the formation and dissolution of the metal chalcogenide in solution.

5. The method of claim 1 wherein said solution is prepared by dissolving a preformed hydrazinium-based precursor in a non-hydrazine-based solvent.

6. The method of claim 1 wherein said solution is prepared by contacting a metal chalcogenide and a salt of an amine to produce an ammonium-based precursor of the metal chalcogenide, which is then contacted with a hydrazine compound and optionally, an elemental chalcogen.

7. The method of claim 1 wherein said solution is applied by a process selected from the group consisting of spin coating dip coating, doctor blading drop casting stamping and printing.

8. The method of claim 1 wherein the annealing is carried out at a temperature of about 50° C. to about 500° C.

9. The method of claim 1 wherein the annealing is carried out at a temperature of about 100° C. to about 350° C.

10. The method of claim 1 wherein the annealing is carried out for about 5 seconds to about 5 hours.

11. The method of claim 1 wherein the annealing is carried out for about 10 minutes to about 30 minutes.

12. The method of claim 1 wherein the annealing is carried out employing a hotplate, in oven/furnace, laser annealing or microwave.

13. The method of claim 1 which comprises depositing multiple layers by iteration to create a greater filling fraction or to layer different materials in the hole.

14. The method of claim 1 wherein the holes have similar lateral dimensions in the plane of the substrate and wherein the dimensions of the holes are about 20 to about 1000 nm.

15. The method of claim 1 wherein the holes have one lateral dimension of about 20 to about 1000 nm and the other lateral dimension which exceeds the first by greater than about 2 times.

16. The method of claim 1 wherein the holes have similar lateral dimensions in the plane of the substrate and wherein the dimensions are less than about 20 nm.

17. The method of claim 1 wherein the holes have one lateral dimension of less than 20 nm and the other lateral dimension which exceeds the first by greater than about 2 times.

18. The method of claim 1 wherein said substrate is subjected to a wetting-promoting cleaning method selected from the group consisting of solvent cleaning, piranha solution treatment, basic (hydroxide) solution treatment, UV-ozone, and oxygen plasma.

19. The method of claim 1 which further comprises depositing a wetting enhancement layer of a material that lines the holes conformally.

20. The method of claim 1 wherein said holes are formed using a block copolymer template.

21. The method of claim 1 wherein said holes are formed by photo- or e beam lithography.
